(19) United States
(12) Patent Application Publication
(10) Pub. No.: US 2020/0152661 A1
(43) Pub. Date: May 14, 2020

(54) STANDARD CELL HAVING MIXED FLIP-WELL AND CONVENTIONAL WELL TRANSISTORS

(71) Applicant: NXP USA, INC., Austin, TX (US)

(72) Inventors: David Russell Tipple, Leander, TX (US); Emmanuel Chukwuma Onyema, Kyle, TX (US)

(21) Appl. No.: 16/184,233

(22) Filed: Nov. 8, 2018

(51) Int. Cl. H01L 27/12; H01L 27/02

(52) U.S. Cl. CPC H01L 27/1203; H01L 27/0207

(57) ABSTRACT

An LVT-RVT cell includes an LVT PMOS transistor adjacent to an RVT NMOS transistor, whereby the LVT and RVT transistors are placed inside a common p-well and are biased using the same voltage potential. The cell thus employs a flipped well for the PMOS transistor and a conventional (unflipped) well for the NMOS transistor. By arranging the LVT-RVT cell in this way, the cell can function at lower voltages, thereby conserving power, while also improving the performance of the composite function. Furthermore, the LVT-RVT cell can be placed adjacent to RVT cells to further reduce power consumption and improve performance of the RVT cells within the block.

### BACKGROUND

### Field of the Disclosure

The present disclosure relates generally to semiconductor devices and more particularly to standard layout cells for semiconductor devices.

### Description of the Related Art

Over time, semiconductor devices (e.g. processors) have employed transistors having smaller and smaller dimensions. However, reducing transistor dimensions presents challenges such as short channel effects (SCEs), parasitic capacitance issues, and the like. One approach to these challenges is the use of Fully Depleted Semiconductor-on-Insulator (FDSOI) technology. An FDSOI transistor typically includes a buried oxide (BOX) insulator on top of the base silicon, and a thin silicon film over the BOX layer to form the channel of the transistor. Because of the thin film structure, the transistor channel is not doped, and the transistor is therefore “fully depleted.”

FDSOI technology presents challenges in semiconductor devices employing different standard transistor layout cells for different transistor threshold voltages. For example, some semiconductor devices employ regular voltage threshold (RVT) cells for transistors to be associated with a “regular” voltage threshold and low voltage threshold (LVT) cells for transistors to be associated with a lower voltage threshold than the RVT cells. Conventional FDSOI RVT cells include a P-type metal-oxide-semiconductor (PMOS) device that exhibits relatively poor performance and N-type devices (NMOS) with slightly higher performance. Further, conventional RVT FDSOI RVT cells are difficult to place in proximity with LVT cells without negatively impacting block size and in turn transistor performance. This difficulty is due to the well structures beneath the BOX layer. In particular, an RVT cell is normally constructed by placing a PMOS device over an n-well and an NMOS device over a p-well, and an LVT cell is constructed by placing a PMOS device over a p-well and an NMOS device over an n-well. It is also common to bias the underlying wells for RVT cells and LVT cells at different potentials requiring even larger spaces to accommodate the well isolation to enable this biasing.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a diagram of a mixed LVT-RVT cell in accordance with at least one embodiment.

FIG. 2 is a diagram of an RVT cell that can share a p-well with the mixed LVT-RVT cell of FIG. 1 in accordance with at least one embodiment.

FIG. 3 is a block diagram illustrating a layout of semiconductor device including LVT-RVT cells of FIG. 1 and RVT cells in accordance with at least one embodiment.

FIG. 4 is a block diagram illustrating an RVT cell of FIG. 2 having an n-well layer within the cell place-and-route boundary in accordance with at least one embodiment.

FIG. 5 is a flow diagram of a method of forming a mixed LVT-RVT cell in accordance with at least one embodiment.

### DETAILED DESCRIPTION

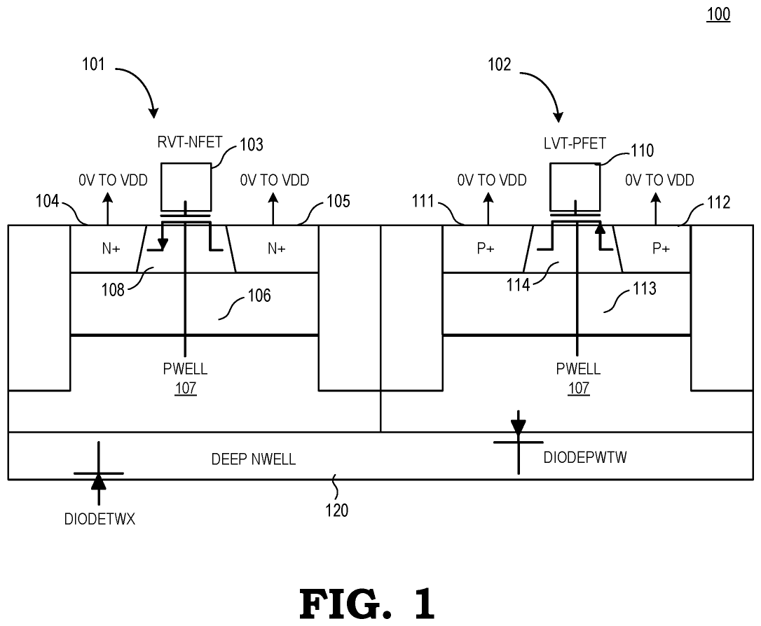

FIGS. 1-4 illustrate techniques for employing a mixed LVT-RVT cell in an FDSOI semiconductor device. The LVT-RVT cell includes an LVT PMOS transistor adjacent to an RVT NMOS transistor, whereby the LVT and RVT transistors are placed inside a common p-well and are biased using the same voltage potential. That is, the cell employs a flipped well for the PMOS transistor and a conventional (unflipped) well for the NMOS transistor. By arranging the LVT-RVT cell in this way, the cell can function at lower voltages, thereby conserving power, while also improving the performance of the composite function. Furthermore, the LVT-RVT cell can be placed adjacent to RVT cells to further reduce power consumption and improve performance of the RVT cells within the block. The LVT PMOS device of the LVT-RVT cell reduces the performance difference inherent in the use of PMOS devices in FDSOI cells, providing performance benefits with a low area penalty.

FIG. 1 illustrates a mixed LVT-RVT cell 100 in accordance with at least one embodiment of the present disclosure. In at least one embodiment, the cell 100 is part of a semiconductor device, such as a processor. The cell 100 can be selected (e.g., by an automated integrated circuit design tool) during design of the semiconductor device to form part of a logic device, such as a logic gate. Based on the device design, the semiconductor device can be manufactured to form and connect the transistors of the cell 100, as well as other components of the semiconductor device, as described further herein.

The cell 100 includes an NMOS transistor (N-FET) 101 and a PMOS transistor (P-FET) 102 formed on a p-type substrate (not shown), with a deep n-well 120 formed over the p-type substrate to provide isolation for the transistors 101 and 102. To form the NMOS transistor 101, a p-well 107 is formed over the n-well 120 and a buried oxide (BOX) insulator layer 106 is formed over a portion of the p-well 107. N-type source and drain regions 104 and 105 are formed over respective portions of the BOX layer 106. A transistor channel 108 is formed by placing a thin silicon film over the BOX layer 106. In at least one embodiment, the silicon film is undoped, so that the transistor channel 108 is fully depleted. A gate 103 is formed over the transistor channel 108.

To form the PMOS transistor 102, the p-well 107 is formed over the n-well 120 as with the NMOS transistor 101. A buried oxide (BOX) insulator layer 113 is formed over a portion of the p-well 107. P-type source and drain regions 111 and 112 are formed over respective portions of the BOX layer 113. A transistor channel 114 is formed, in similar fashion to the transistor channel 108, by placing a thin silicon film over the BOX layer 113. In at least one embodiment, as with the transistor channel 108, the silicon film is undoped, so that the transistor channel 108 is fully depleted. A gate 103 is formed over the transistor channel 108.

Thus, in the illustrated embodiment of the cell 100, the NMOS transistor 101 and PMOS transistor 102 are formed over a common p-well 107. For the NMOS transistor 101, the p-well 107 is a conventional well structure. In different embodiments, the well structure has can be biased to increase performance or reduce leakage using a single well potential on well 107. In contrast, for the PMOS transistor 102 the p-well 107 forms a flipped well structure that increases the performance of the PMOS device and lowers the operating threshold (VT) of the device. The common well structure enables both the NMOS and PMOS to be concurrently forward biased, thereby increasing the operating speed or reverse biased reducing the leakage power consumption with a single well voltage. Thus, for a given semiconductor device, the NMOS transistor 101 can be employed as an RVT transistor while the PMOS transistor 102 can be employed as an LVT transistor. In at least one embodiment, the depicted structure enables biasing of the P-well using a single supply voltage with the natural bias condition of zero volts providing the base operating point. This provides the option to adjust the speed or operating point using a single control voltage on the P-well.

It will be appreciated that, in at least one embodiment, the threshold voltage of the transistors 101 and 102 can be modified via forward body biasing or reverse body biasing. In at least one embodiment, the transistors 101 and 102 are biased with the same bias voltage to reduce leakage. In at least one embodiment, the PMOS transistor 102 has a lower threshold voltage than the PMOS transistor of a conventional FDSOI cell. For example, in at least one embodiment the transistors 101 and 102 can be configured to operate at a supply voltage well below 0.45 volts even in a stacked transistor configuration. Further, in at least one embodiment the NMOS transistor exhibits better performance than the RVT transistors of a conventional FDSOI cell that employs a PMOS inside an n-well.

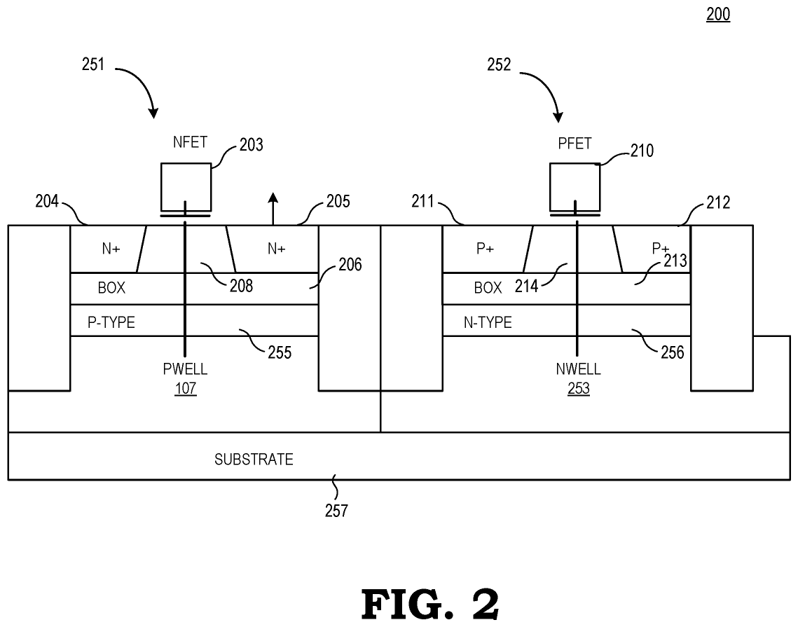

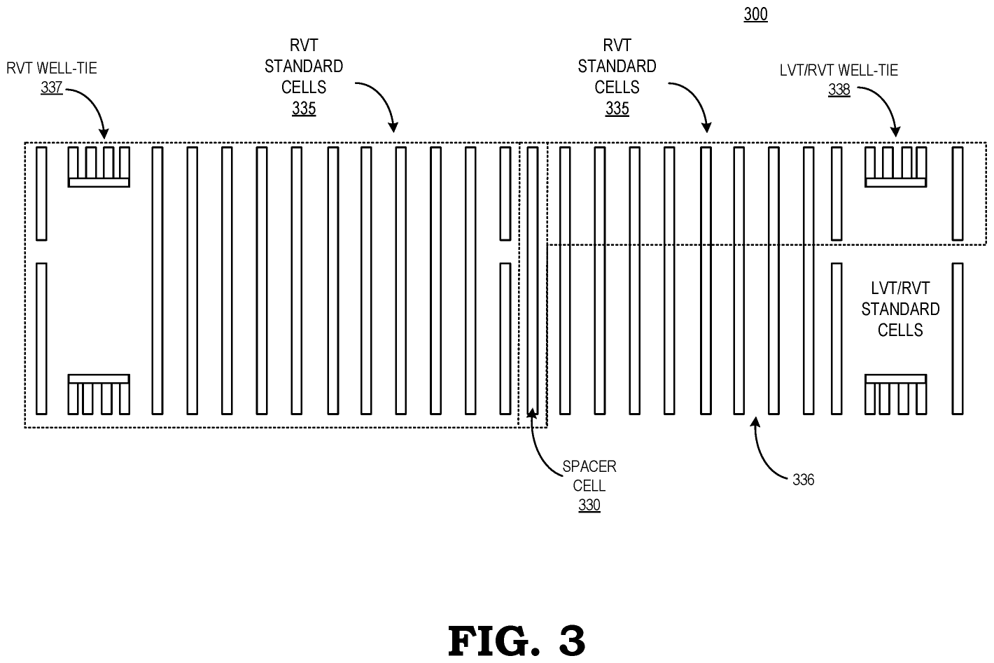

In at least one embodiment, the cell 100 can be placed in a semiconductor device so that the cell 100 vertically abuts an RVT cell. The cell 100 thereby supports flexible design of semiconductor devices. This can be better understood with reference to FIGS. 2 and 3. FIG. 2 illustrates an RVT cell 200 that includes an NMOS transistor 251 and a PMOS transistor 252 formed over the semiconductor substrate 257. To form the NMOS transistor 251, the p-well 107 is formed over the substrate 257 and p-type material 255 is formed over the p-well 107. A BOX layer 206 is formed over the p-type material 255. N-type source and drain regions 204 and 205 are formed over respective portions of the BOX layer 206. A transistor channel 208 is formed by placing a thin silicon film over the BOX layer 106. In at least one embodiment, the silicon film is undoped, so that the transistor channel 208 is fully depleted. A gate 203 is formed over the transistor channel 108.

To form the PMOS transistor 252, an n-well 253 is formed over the substrate 257 and n-type material 256 is formed over the n-well 253. A BOX layer 213 is formed over the n-type material 256. P-type source and drain regions 211 and 212 are formed over respective portions of the BOX layer 213. A transistor channel 214 is formed by placing a thin silicon film over the BOX layer 213. In at least one embodiment, the silicon film is undoped, so that the transistor channel 214 is fully depleted. A gate 210 is formed over the transistor channel 214.

In the illustrated embodiment, both the NMOS transistor 251 and the PMOS transistor 252 have conventional well structures that lower the amount of charge retained at the respective source and drain regions. The voltage threshold for both the NMOS transistor 251 and the PMOS transistor 252 is thus increased and is substantially the same as the threshold voltage for the NMOS transistor 101 of FIG. 1. Accordingly, the cell 100 can be employed as an RVT cell for a semiconductor device. Furthermore, the NMOS transistor 251 shares the p-well 107 with the transistors 101 and 102 of FIG. 1. This allows the cell 100 of FIG. 1 and the cell 200 of FIG. 2 to be abutted in the semiconductor device, thereby supporting more flexibility in the design and layout of semiconductor devices.

FIG. 3 illustrates an example semiconductor device 300 having RVT cells vertically abutted with LVT/RVT cells in accordance with at least one embodiment. In the depicted example, the semiconductor device 300 includes a plurality of RVT cells 335, wherein each of the RVT cells 335 has the same arrangement as the cell 200 of FIG. 2. In addition, the semiconductor device 300 includes a plurality of LVT/RVT cells 336, wherein each of the LVT/RVT cells has the same arrangement as the cell 100 of FIG. 1. As depicted, a top edge of the LVT/RVT cells 336 corresponds to a bottom edge of a subset of the RVT cells 335, so that the LVT/RVT cells 336 are vertically abutted with the subset of the RVT cells 335. This allows each of the LVT/RVT cells 336 to share a p-well (e.g., p-well 337) with a corresponding one of the subset of RVT cells 335.

The semiconductor device 300 also includes a spacer cell 330 placed between a subset of the RVT cells 335 and the LVT/RVT cells 336. In at least one embodiment, the spacer cell 330 includes an n-well configured not to interfere with the LVT/RVT cells while also enabling the mating of the well extension of the RVT cells 335. In at least one embodiment, the spacer cell 330 includes an RVT layer that has been adjusted to provide the continuity of the LVT/RVT cells 336 and not interfere with the LVT (PMOS) section these cells. The RVT layer also enables mating with the RVT layer of the PMOS side of the RVT cells 335.

The semiconductor device 300 also includes RVT well tie 337 for the RVT cells 335 and LVT/RVT well tie 338 for the LVT/RVT cells 336. The well ties 337 and 338 connect the wells of the respective cells to voltage sources in order to bias the different transistors. In at least one embodiment, the well tie for the RVT cells 335 can be shared by the LVT/RVT cells, further simplifying the layout of the semiconductor device 300. If the whole block of cells 335 are placed in a deep n-well, the base RVT well tie can be used to service all the RVT PMOS devices of within the block even when LVT/RVT cells are dispersed through the block. The n-well conductivity is carried through the deep n-well and in turn produces an isolated p-well under the RVT NMOS and LVT flipped well PMOS devices.

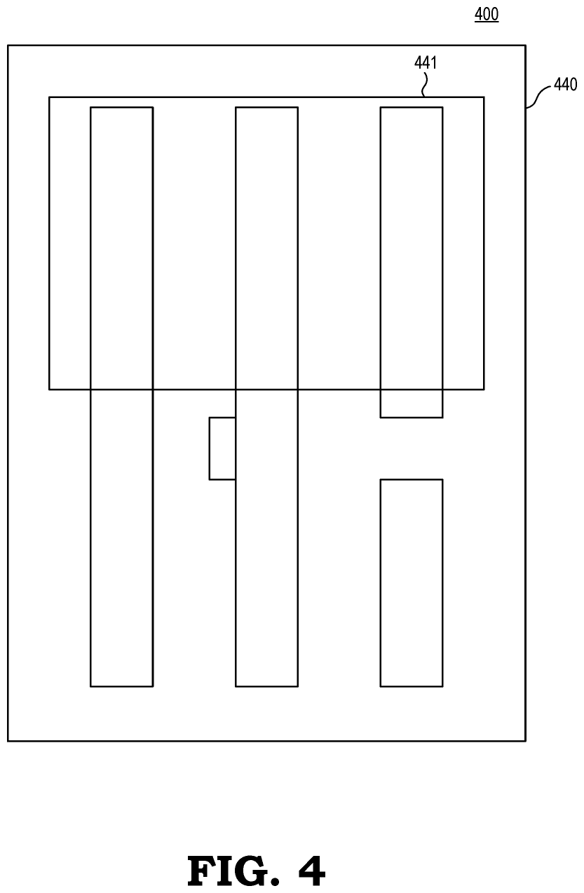

In at least one embodiment, the RVT cell layout can be adjusted to further support abutment of the LVT/RVT cells with the RVT cells. An example is illustrated at FIG. 4. In particular, FIG. 4 depicts a layout 400 of the RVT cell 200 (FIG. 2). The layout 400 includes a place-and-route (PR) boundary 440 that defines the edges of the cell 200. Conventionally, the n-well of an RVT cell is extended beyond the PR boundary. However, to support abutment of the LVT/RVT cells, the layout 400 is configured so that the n-well 441, corresponding to n-well 253 for the transistor 252, is pulled back to be within the PR boundary 440.

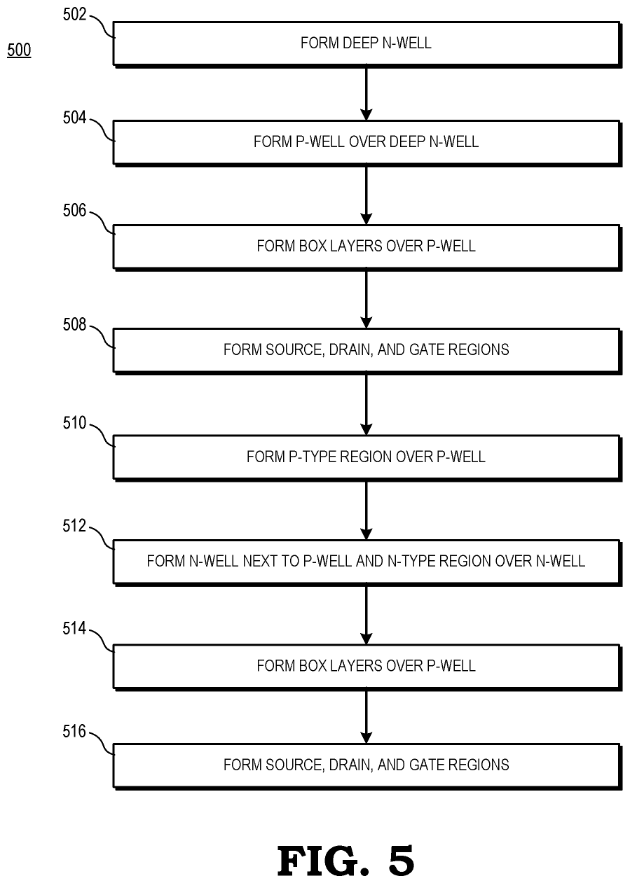

FIG. 5 is a flow diagram of a method 500 of forming a mixed LVT-RVT cell in accordance with at least one embodiment. The method 500 is described with respect to an example formation of the cell 100 of FIG. 1 and the cell 200 of FIG. 2. The formation of the different layers, as set forth herein, can be performed according to any standard FDSOI semiconductor formation techniques. In addition, although different operations are described separately with respect to different blocks of the method 500, it will be appreciated that the different operations can be performed concurrently or as part of the same process. For example, although the formation of different portions of the cell 100 and the cell 200 are described separately with respect to different blocks, in at least one embodiment one or more of the different described portions, such as the formation of the p-well 107, can be formed for both cells concurrently.

At block 502, the deep n-well 120 is formed over the semiconductor substrate 257. At block 504 the p-well 107 is formed over the deep n-well 120 for the cells 100 and 200. At block 506, the BOX layers 106 and 116 are formed over the p-well 107. At block 508, the source and drain regions 104, 105, 111, and 112, as well as the channels 108 and 114 are formed over the BOX layers 106 and 113, respectively. The gates 103 and 110 are then formed to connect to the channels 108 and 114, respectively, thereby forming the transistors 101 and 102 for the cell 100.

To form the cell 200, at block 510, the p-type region 255 is formed over the p-well 107. At block 512, the n-well 253 is formed next to the p-well 107 and the n-type region 256 is formed next to the p-type region 255. At block 514 the BOX layers 206 and 213 are formed over the p-type region 255 and the n-type region 256, respectively. At block 516 the source and drain regions 204 and 205 and the channel 208 are formed over the BOX layer 206. The gate 203 is formed over the transistor channel 208. Similarly, the source and drain regions 211 and 212 and the transistor channel 214 are formed over the BOX layer 213. The gate 210 is formed over the transistor channel 214. Thus, the cell 200 is formed such that, the transistor 251 shares the p-well 107 with the cell 100. This configuration supports abutment of the cell 100 with the cell 200, thus providing for better performance and improved leakage control while reducing the area costs of the better performance.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A semiconductor device comprising:
a first cell comprising:
a first FDSOI NMOS transistor comprising a p-well and a first buried oxide (BOX) insulator layer overlying the p-well; and
a first FDSOI PMOS transistor comprising a second BOX layer over the the p-well to share the p-well with the first FDSOI NMOS transistor.

2. The semiconductor device of claim 1, wherein the first FDSOI NMOS transistor is associated with a first threshold voltage and the first FDSOI PMOS transistor is associated with a second threshold voltage, the second threshold voltage different from the first threshold voltage.

3. The semiconductor device of claim 2, wherein the first threshold voltage is higher than the second threshold voltage.

4. The semiconductor device of claim 1, wherein the first FDSOI NMOS transistor and the first FDSOI PMOS transistor are biased with the same voltage potential.

5. The semiconductor device of claim 1, further comprising:
a second cell, comprising:
a second FDSOI NMOS transistor comprising a p-type region overlying the p-well to share the p-well with the first FDSOI NMOS transistor and the first FDSOI PMOS transistor.

6. The semiconductor device of claim 5, wherein the second cell further comprises a second FDSOI PMOS transistor comprising an n-well.

7. The semiconductor device of claim 5, wherein the first FDSOI NMOS transistor and the second FDSOI NMOS transistor are associated with higher threshold voltages than the first FDSOI PMOS transistor.

8. The semiconductor device of claim 5, wherein the first cell abuts the second cell in a layout of the semiconductor device.

9. The semiconductor device of claim 5 further comprising a spacer cell adjacent to the first cell and the second cell.

10. A semiconductor device, comprising:
a first cell, including:
a deep n-well;
a p-well formed over the deep n-well;
a first FDSOI transistor comprising:
a first BOX layer formed over the p-well; and
first source and drain regions formed over the first box layer; and
a second FDSOI transistor comprising:
a second BOX layer formed over the p-well; and
second source and drain regions formed over the first box layer.

11. The semiconductor device of claim 10, wherein the first FDSOI transistor is associated with a first threshold voltage and the second FDSOI transistor is associated with a second threshold voltage, the second threshold voltage different from the first threshold voltage.

12. The semiconductor device of claim 11, wherein the first threshold voltage is higher than the second threshold voltage.

13. The semiconductor device of claim 10, wherein the first FDSOI transistor and the second FDSOI transistor are biased with the same voltage potential.

14. The semiconductor device of claim 10, further comprising:
a second cell, comprising:
a third FDSOI transistor comprising
the p-well;
a third box layer formed over the p-well; and
third source and drain regions formed over the first box layer.

15. The semiconductor device of claim 14, wherein the second cell further comprises a second FDSOI PMOS transistor comprising an n-well.

16. The semiconductor device of claim 15, wherein the first FDSOI transistor and the third FDSOI transistor are associated with higher threshold voltages than the second FDSOI transistor.

17. The semiconductor device of claim 15, wherein the first cell abuts the second cell in a layout of the semiconductor device.

18. The semiconductor device of claim 15 further comprising a spacer cell adjacent to the first cell and the second cell.

19. A method of forming a semiconductor device, comprising:
forming a p-well;
forming a first BOX layer and a second BOX layer over the p-well;
forming first source, drain and gate regions over the first BOX layer to form a first FDSOI NMOS transistor;
forming second source drain and gate regions over the second BOX layer to form a first FDSOI PMOS transistor.

20. The method of claim 19, further comprising:
forming a p-type region over the p-well;
forming a third BOX layer over the p-type region; and
forming third source, drain and gate regions over the third BOX layer to form a second FDSOI NMOS transistor.
